(19) United States
(12) Patent Application Publication
(10) Pub. No.: US 2008/0043407 A1
(43) Pub. Date: Feb. 21, 2008

(54) PORTABLE COMPUTER SECURITY DEVICE THAT INCLUDES A PROTECTIVE MOUNTING STRUCTURE FOR A LCD

(75) Inventor: Noah L. Anglin, San Jose, CA (US)

Correspondence Address: SCHWEGMAN, LUNDBERG & WOESSNER, P.A., P.O. BOX 2938, MINNEAPOLIS, MN, 55402, US

(73) Assignee: Secure Computing Corporation

(21) Appl. No.: 11/464,983

(22) Filed: Aug. 16, 2006

(51) Int. Cl. H05K 5/00

(52) U.S. Cl. 361/679

(57) ABSTRACT

The present invention relates to a portable computer security device that includes a protective mounting structure for an LCD. The portable computer security device includes a cover and a base and further includes an integrated circuit and a LCD assembly that are each positioned between the cover and the base. The LCD assembly is electrically connected to the integrated circuit. The integrated circuit generates random numbers for display on the LCD assembly such that the random numbers may be used to provide access to a computer system. In addition, the LCD assembly is aligned with an opening in the cover to permit observation of the LCD assembly through the opening in the cover. The portable computer security device further includes a damping member. The damping member is positioned between the LCD assembly and the cover to reduce shock and vibration forces that are generated on the LCD assembly.

### FIELD

The present invention relates to a portable computer security device, and in particular to a portable computer security device that includes a protective mounting structure for an LCD.

### BACKGROUND

Portable computer security devices are commonly used to provide a point for policy enforcement and reporting as it relates to computer system security. The use of portable computer security devices also permits anywhere, anytime remote access to applications, data and networks.

Most portable security devices are used to provide convenient, secure wireless and wired LAN access for individuals such as employees, contractors and guests. A portable computer security device may serve as a reliable mechanism to enable configuration compliance while ensuring that every end-point device adheres to a security policy.

The endpoint security that is enabled by portable computer security devices ensures that only properly configured end-point devices can access the network. Portable computer security devices serve as a vital component to a complete identity and access management strategy for computing systems.

Manufacturers are constantly trying to make portable computer security devices as small and adaptable as possible. In addition, many portable computer security devices include a glass liquid crystal display (hereafter LCD) that is used to display computer system information to a user of a computer system. One of the drawbacks with existing portable computer security devices is that these glass LCDs are too easily damaged during everyday use and handling.

There is a need for a portable computer security device that is relatively small and includes a glass LCD which is more capable of standing up to the rigors of everyday use of the portable computer security device. The portable computer security device should incorporate the features, quality and styling of existing portable computer security devices while being capable of protecting a glass LCD that is part of the portable computer security device.

### SUMMARY OF THE INVENTION

The present invention relates to a portable computer security device that includes a protective mounting structure for an LCD. The portable computer security device is relatively small and includes a glass LCD that is better able to stand up to the rigors of everyday use of the portable computer security device.

The portable computer security device includes a cover and a base. The portable computer security device further includes an integrated circuit and a LCD assembly that are each positioned between the cover and the base.

The LCD assembly is electrically connected to the integrated circuit. The integrated circuit generates random numbers for display on the LCD assembly such that the random numbers may be used to provide access to a computer system.

In addition, the LCD assembly is aligned with an opening in the cover to permit observation of the LCD assembly through the opening in the cover. In some embodiments, the LCD assembly includes a glass LCD that provides a relatively high quality image on the LCD assembly.

The portable computer security device further includes a damping member. The damping member is positioned between the LCD assembly and the cover to reduce shock and vibration forces that are generated on the LCD assembly.

The purposes and features of the present invention will be set forth in the description that follows. Additional features of the invention may be realized and attained by the product and processes particularly pointed out in the written description and claims hereof, as well as from the appended drawings.

It is to be understood that both the foregoing general description and the following detailed description are exemplary and are intended to provide further explanation of the invention claimed. The accompanying drawings, which are incorporated in and constitute part of this specification, are included to illustrate and provide a further understanding of the invention.

### BRIEF DESCRIPTION OF THE DRAWINGS

The present invention will be more fully understood, and further features will become apparent, when reference is made to the following detailed description and the accompanying drawings. The drawings are merely representative and are not intended to limit the scope of the claims. Like parts depicted in the drawings are referred to by the same reference numerals.

FIG. 1 is a perspective view of a portable computer security device.

FIG. 2 is an enlarged perspective view illustrating an example LCD assembly and damping member that may be used in the portable computer security device shown in FIG. 1.

FIG. 3 is an enlarged side schematic view illustrating an example LCD assembly and a portion of an example cover that may used in the portable computer security device shown in FIG. 1.

FIG. 4 is a side schematic view illustrating a portion of the example portable computer security device shown in FIG. 1.

FIG. 5 is a perspective view of the portable computer security device shown in FIG. 1 with the cover, damping member and LCD assembly removed from the Figure.

FIG. 6 is an electrical schematic of an example integrated circuit that may be used in the portable computer security device of FIG. 1.

### DETAILED DESCRIPTION OF THE INVENTION

The following detailed description references the accompanying drawings which show some example embodiments of the invention. These example embodiments are described in sufficient detail to enable those skilled in the art to practice the invention. It is to be understood that other embodiments may be utilized, or structural changes made, such that the detailed description should not be considered as limiting the scope of the claims.

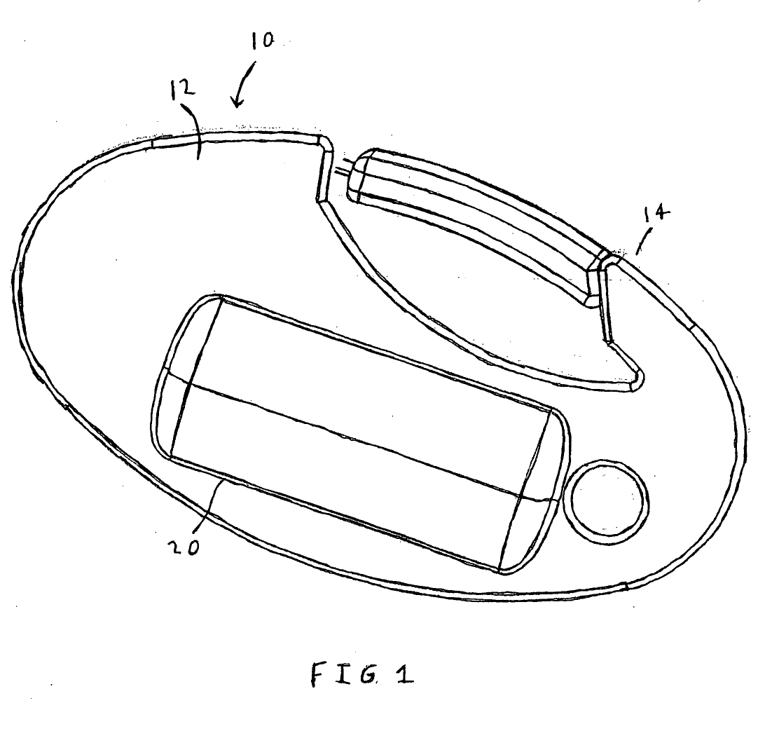

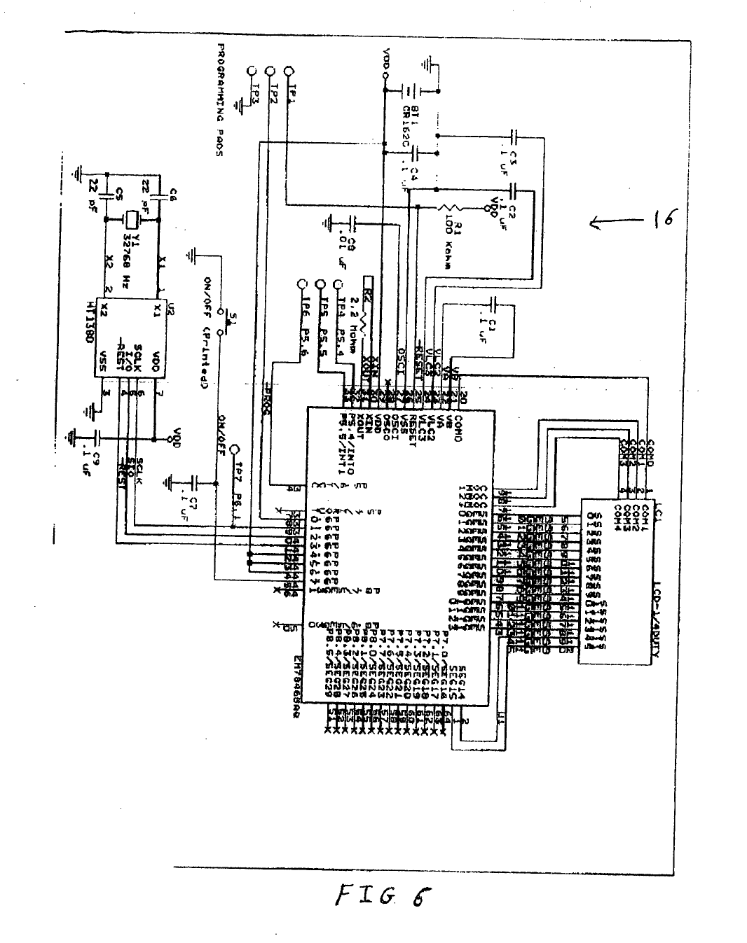

FIGS. 1-5 illustrate an example portable computer security device 10. The portable computer security device 10 includes a cover 12 and a base 14. The portable computer security device 10 further includes an integrated circuit 16 (not visible in FIGS. 1-5) that is positioned between the cover 12 and the base 14. An example integrated circuit 16 is shown in FIG. 6.

The portable computer security device 10 further includes a LCD assembly 18 that is positioned between the cover 12 and the base 14. The LCD assembly 18 is electrically connected to the integrated circuit 16. In addition, the LCD assembly 18 is aligned with an opening 20 in the cover 12 to permit observation of the LCD assembly 18 through the opening 20 in the cover 12.

In some embodiments, the LCD assembly 18 includes a glass LCD to provide a relatively high quality image on the LCD assembly 18. As an example, the LCD assembly 18 may include two thin layers of glass that are combined with films and other materials.

It should be noted that the LCD may be any type of LCD that is known now or discovered in the future. In addition, the size and design of the LCD will depend in part on the size and shape of the cover 12 and the base 14 (among other factors).

The integrated circuit 16 generates random numbers for display on the LCD assembly 18 such that the random numbers may be used to provide access to a computer system. It should be noted that the random numbers may be generated in an event synchronous mode or a timed synchronous mode.

The portable computer security device 10 further includes a damping member 22 that is positioned between the LCD assembly 18 and the cover 12 to reduce shock and vibration forces that are generated on the LCD assembly 18. One example material for the damping member 22 includes a silicone gel that has a durometer of around 20 on Shore A scale.

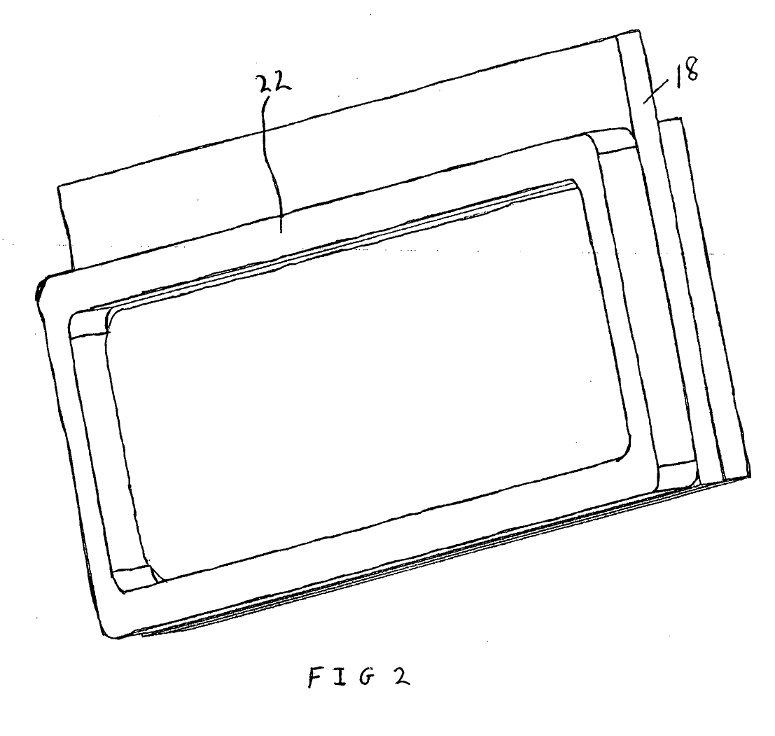

As shown most clearly in FIG. 2, the damping member 22 may have a rectangular outer shape and include an opening such that the LCD assembly 18 is visible through the opening in the damping member 22. The size and design of the damping member 22 will depend in part on the size and shape of the LCD assembly 18 as well as the structural design of the cover 12 and the base 14 (among other factors).

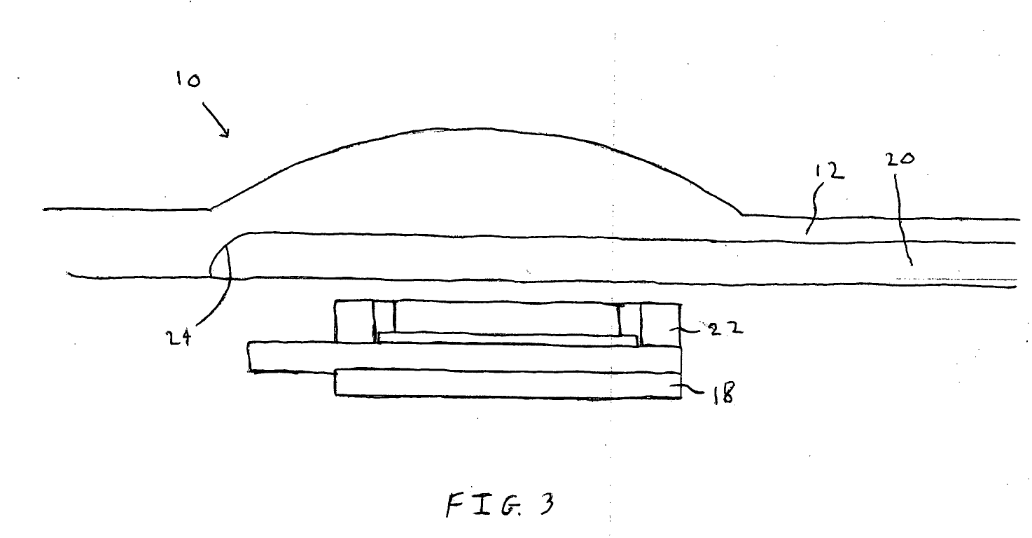

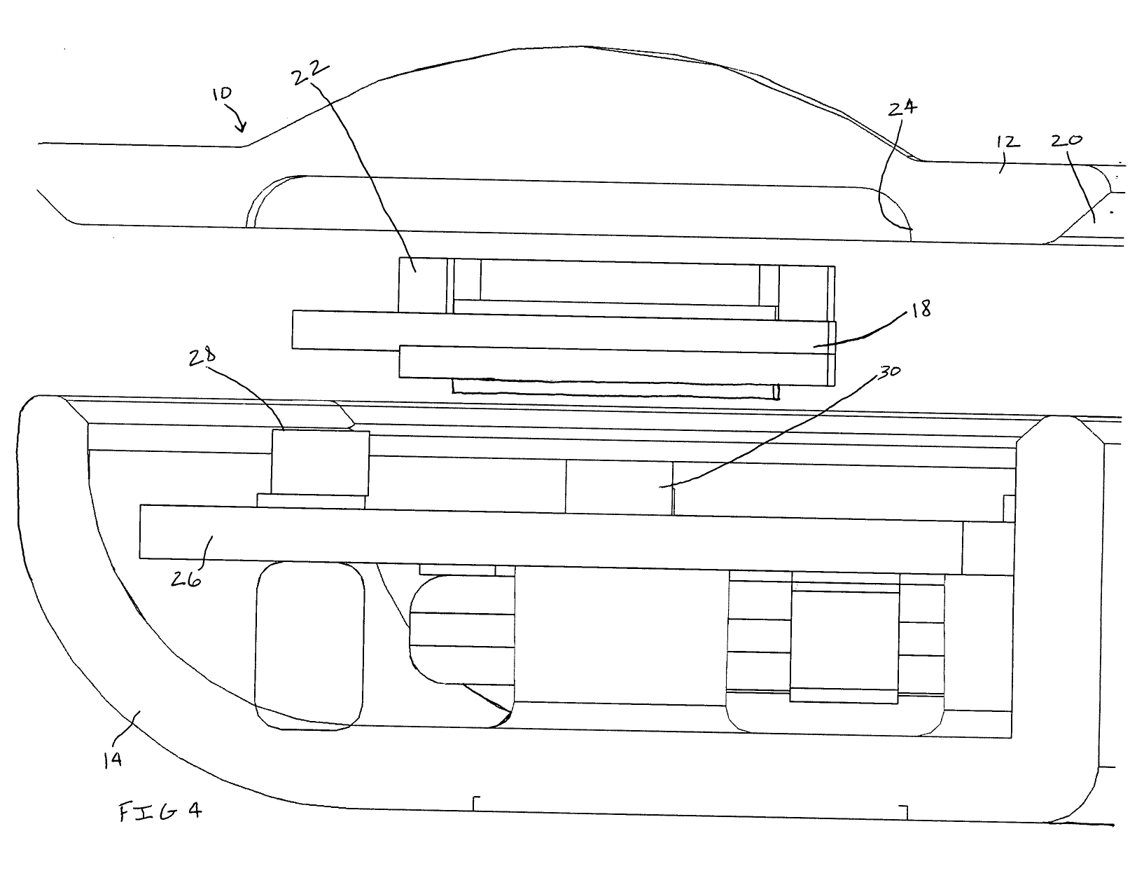

As shown most clearly in FIGS. 3 and 4, the cover 12 includes a recess 24 such that the damping member 22 and possibly the LCD assembly 18 are located within the recess 24 in the cover 12 when the base 14 is secured to the cover 12. The size and design of the recess 24 and the LCD assembly 18 will depend in part on the structural design of the cover 12 and the base 14 (among other factors).

In some embodiments, the damping member 22 touches the cover 12. It should be noted that embodiments are contemplated where the damping member 22 engages the cover 12 through another part of the portable computer security device 10.

In addition, the damping member 22 touches the LCD assembly 18. It should be noted that embodiments are contemplated where the damping member 22 engages the LCD assembly 18 through another part of the portable computer security device 10.

The cover 12 may be attached to the base 14 in any manner that is known now or discovered in the future. As an example, the cover 12 may be secured to the base 14 using an adhesive. The type of attachment between the cover 12 and the base 14 will depend in part on the structural design of the cover 12 and the base 14 (among other factors). Example materials for the cover 12 and the base 14 include metal and plastic.

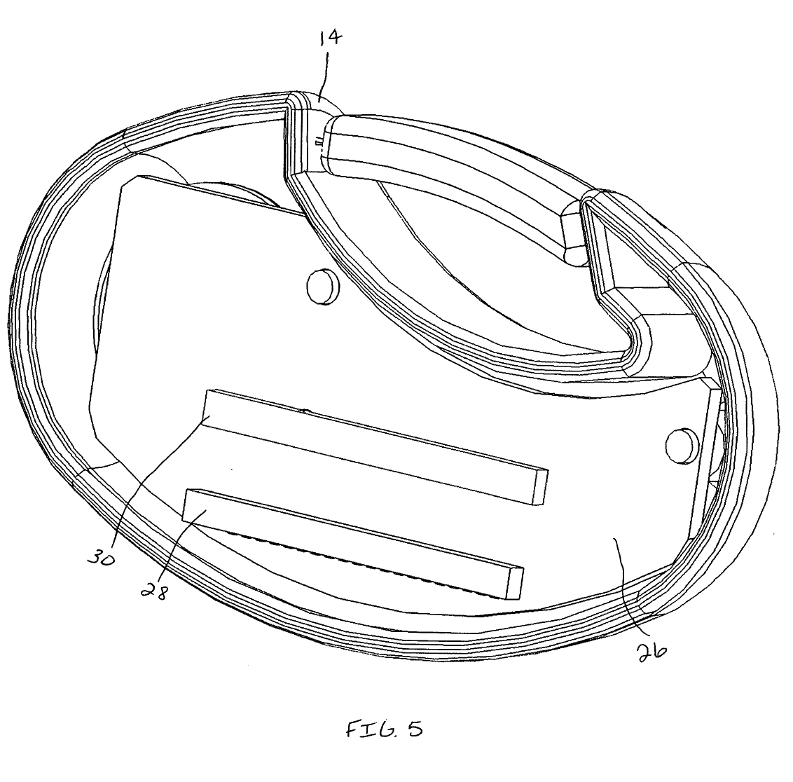

In some embodiments, the integrated circuit 16 is part of a circuit board 26 (see FIGS. 4 and 5) that serves to form part of the electrical connection between the integrated circuit 16 and the LCD assembly 18. As shown most clearly in FIGS. 4 and 5, the LCD assembly 18 may be electrically connected to the circuit board 26 using a flexible conductor 28. It should be noted that the flexible conductor 28 may be any type of flexible conductor that is known now or discovered in the future. As an example, the flexible conductor 28 may be a zebra strip.

In the illustrated example embodiment, the damping member 22 is a first damping member 22 and the portable computer security device further comprises a second damping member 30. The second damping member 30 is between the LCD assembly 18 and the circuit board 26 to reduce shock and vibration forces that are generated on the LCD assembly 18.

In some embodiments, the second damping member 30 touches the circuit board 26. It should be noted that embodiments are contemplated where the second damping member 30 engages the circuit board 26 through another part of the portable computer security device 10.

In addition, the second damping member 30 touches the LCD assembly 18. It should be noted that embodiments are contemplated where the second damping member 30 engages the LCD assembly 18 through another part of the portable computer security device 10.

As shown most clearly in FIG. 5, the second damping member 30 may have a linear shape. The size and shape of the second damping member 30 will depend in part on the size and shape of the LCD assembly 18 as well as the circuit design of the circuit board 26 (among other factors).

Note that the LCD assembly 18 is completely isolated from the rigid components that are part of the portable computer security device 10 by the first and second damping members 22, 30. Therefore, the shock and vibration forces that would otherwise normally be generated upon the LCD assembly 18 during everyday use of the portable computer security device 10 are reduced by the first and second damping members 22, 30.

The portable computer security devices 10 described herein are relatively small yet are still capable of protecting a glass LCD that is part of the portable computer security devices 10. The ability to protect the glass LCD makes the portable computer security device 10 more suitable for everyday use.

While the invention has been described in detail with respect to the specific aspects thereof, it will be appreciated that those skilled in the art, upon attaining an understanding of the foregoing, may readily conceive of alterations to, variations of, and equivalents to these aspects which fall within the spirit and scope of the present invention, which should be assessed accordingly to that of the appended claims.

I claim:

1. A portable computer security device comprising:
a cover;
a base;
an integrated circuit within the base;
a LCD assembly positioned between the cover and the base such that the LCD assembly is aligned with an opening in the cover to permit observation of the LCD assembly through the opening in the cover, the LCD assembly being electrically connected to the integrated circuit, the integrated circuit generating random numbers for display on the LCD such that the random numbers are used to provide access to a computer system; and
a damping member positioned between the LCD assembly and the cover to reduce shock and vibration forces that are generated on the LCD assembly.

2. The portable computer security device of claim 1 wherein the damping member includes an opening such that the LCD assembly is visible through the opening in the damping member.

3. The portable computer security device of claim 1 wherein the damping member has a rectangular outer shape.

4. The portable computer security device of claim 1 wherein the damping member is formed of a silicone gel.

5. The portable computer security device of claim 1 wherein the cover includes a recess such that the damping member is positioned within the recess in the cover.

6. The portable computer security device of claim 1 wherein the damping member touches the cover and touches the LCD assembly.

7. The portable computer security device of claim 1 wherein the integrated circuit is part of a circuit board.

8. The portable computer security device of claim 7 wherein the LCD assembly is electrically connected to the circuit board using a flexible conductor.

9. The portable computer security device of claim 8 wherein the flexible conductor is a zebra strip.

10. The portable computer security device of claim 7 wherein the damping member is a first damping member and the portable computer security device further comprises a second damping member, the second damping member being between the LCD assembly and the circuit board to reduce shock and vibration forces that are generated on the LCD assembly.

11. The portable computer security device of claim 10 wherein the second damping member touches the circuit board and touches the LCD assembly.

12. The portable computer security device of claim 10 wherein the second damping member has a linear shape.

13. The portable computer security device of claim 1 wherein the LCD assembly includes a glass LCD.

14. The portable computer security device of claim 13 wherein the glass LCD has a rectangular shape.
